(19) United States
(12) Patent Application Publication
(10) Pub. No.: US 2026/0282417 A1
(43) Pub. Date: Sep. 17, 2026

(54) HIGH-ELECTRON-MOBILITY TRANSISTORS WITH A PATTERNED BARRIER LAYER

(71) Applicant: GlobalFoundries U.S. Inc., Malta, NY (US)

(72) Inventor: Abhinay Sandupatla, Leuven (BE)

(21) Appl. No.: 19/043,557

(22) Filed: Feb. 3, 2025

(51) Int. Cl. H10D 30/47; H10D 30/01; H10D 62/10; H10D 62/824

(52) U.S. Cl. CPC H10D 30/475; H10D 30/015; H10D 62/116; H10D 62/824

(57) ABSTRACT

Structures for a high-electron-mobility transistor and methods of forming such structures. The structure comprises a layer stack including a first layer and a second layer on the first layer. The first layer comprises a first III-V compound semiconductor material, the second layer comprises a second III-V compound semiconductor material, and the second layer includes a first section and a second section spaced from the first section by a gap. The structure further comprises a high-electron-mobility transistor including a gate overlying the gap, the gate laterally positioned between the first section of the second layer and the second section of the second layer.

This invention was made with government support under HQ0727790700 awarded by the Defense Microelectronics Activity. The government has certain rights in the invention.

### BACKGROUND

The disclosure relates to semiconductor device fabrication and integrated circuits and, more specifically, to structures for a high-electron-mobility transistor and methods of forming such structures.

Compound semiconductors are characterized by advantageous material properties, such as a carrier mobility that is higher than the carrier mobility of silicon and a wider band gap than silicon, that can be exploited to fabricate device structures. Compound semiconductors may include, for example, Group III elements (e.g., aluminum, gallium, and/or indium) and Group V elements (e.g., nitrogen, phosphorus, arsenic, and/or antimony) combined with the Group III elements.

High-electron-mobility transistors based on compound semiconductors can be deployed in certain integrated circuit applications, such as high-voltage power electronics. A high-electron-mobility transistor may include a heterojunction between crystalline compound semiconductor materials having different band gaps, such as a heterojunction between binary gallium nitride and trinary aluminum-gallium nitride. During operation, a two-dimensional electron gas is formed near an interface at the heterojunction and defines the channel of the high-electron-mobility transistor.

A high-electron-mobility transistor is characterized by multiple terminals, namely a gate, a source ohmic contact, and a drain ohmic contact. The gate is used to control carrier flow between the source ohmic contact and the drain ohmic contact. A conventional high-electron-mobility transistor may exhibit unacceptable electrical parameters, such as on-resistance and transconductance, that are a consequence of an elevated device resistance.

Improved structures for a high-electron-mobility transistor and methods of forming such structures are needed.

### SUMMARY

In an embodiment of the invention, a structure comprises a layer stack including a first layer and a second layer on the first layer. The first layer comprises a first III-V compound semiconductor material, the second layer comprises a second III-V compound semiconductor material, and the second layer includes a first section and a second section spaced from the first section by a gap. The structure further comprises a high-electron-mobility transistor including a gate overlying the gap, the gate laterally positioned between the first section of the second layer and the second section of the second layer.

In an embodiment of the invention, a method comprises forming a layer stack including a first layer and a second layer on the first layer. The first layer comprises a first III-V compound semiconductor material, the second layer comprises a second III-V compound semiconductor material, and the second layer includes a first section and a second section that is spaced from the first section by a gap. The method further comprises forming a high-electron-mobility transistor including a gate that overlies the gap. The gate is laterally positioned between the first section of the second layer and the second section of the second layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure at an initial fabrication stage of a processing method in accordance with embodiments of the invention.

FIG. 2 is a top view of the structure at a fabrication stage subsequent to FIG. 1.

FIG. 2A is a cross-sectional view of the structure taken generally along line 2A-2A in FIG. 2.

FIG. 3 is a cross-sectional view of the structure at a fabrication stage subsequent to FIGS. 2, 2A.

FIG. 4 is a cross-sectional view of the structure at a fabrication stage subsequent to FIG. 3.

FIG. 5 is a cross-sectional view of a structure in accordance with alternative embodiments of the invention.

FIG. 6 is a top view of a structure in accordance with alternative embodiments of the invention.

FIG. 7 is a top view of a structure in accordance with alternative embodiments of the invention.

FIG. 8 is a top view of a structure in accordance with alternative embodiments of the invention.

### DETAILED DESCRIPTION

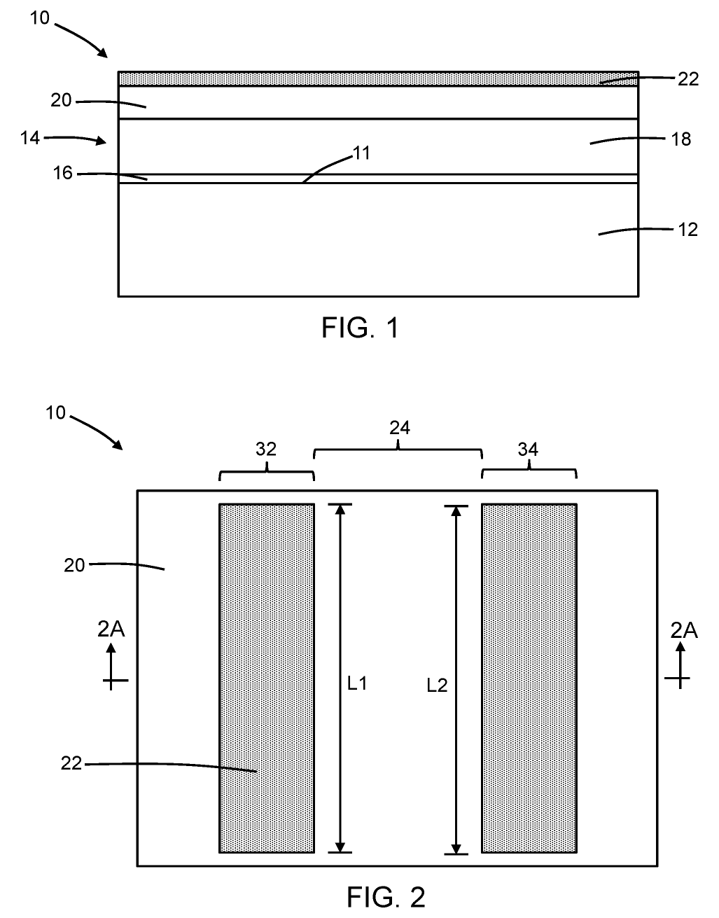

With reference to FIG. 1 and in accordance with embodiments of the invention, a structure 10 for a high-electron-mobility transistor may include a layer stack 14 that is formed on a top surface 11 of a substrate 12. The substrate 12 may be comprised of a single-crystal semiconductor material, such as single-crystal silicon. In an embodiment, the single-crystal semiconductor material of the substrate 12 may have a diamond crystal lattice structure with a <111> crystal orientation. The substrate 12 may be doped to have, for example, p-type conductivity. In alternative embodiments, the substrate 12 may be a different type of substrate, such as a sapphire substrate, an engineered substrate, a silicon-on-insulator substrate, a silicon carbide substrate, etc. The top surface 11 of the substrate 12 may represent a horizontal plane in a representative frame of reference.

The layer stack 14 may include a seed layer 16, a buffer layer 18, a channel layer 20, and a spacer layer 22. The layers 16, 18, 20, 22 may be serially deposited using an epitaxial growth process to form the layer stack 14. Each of the layers 16, 18, 20, 22 of the layer stack 14 may have a crystal structure that is single crystal or, alternatively, a crystal structure that is substantially single crystal with varying levels of crystalline defectivity present. The seed layer 16, which provides a thin nucleation layer for the growth of the buffer layer 18, may be comprised of, for example, aluminum nitride. The buffer layer 18 may be comprised of one or more binary or ternary III-V compound semiconductor materials, such as aluminum gallium nitride, gallium nitride, aluminum nitride, or a layered combination of these materials. The buffer layer 18 is tailored in terms of material composition, doping, layering, and/or layer thickness to accommodate lattice mismatch, thermal property differences, and mechanical property differences between the material of the substrate 12 and the material of the channel layer 20. The channel layer 20, which is positioned between the buffer layer 18 and the spacer layer 22, may be comprised of a binary III-V compound semiconductor material, such as gallium nitride. The channel layer 20 may include a sublayer comprised of undoped gallium nitride adjacent to the spacer layer 22 and a sublayer comprised of doped gallium nitride adjacent to the buffer layer 18. During operation of the high-electron-mobility transistor, a two-dimensional electron gas exists inside the channel layer 20.

The seed layer 16, the buffer layer 18, and the channel layer 20 are positioned between the substrate 12 and the spacer layer 22. In an embodiment, the spacer layer 22 may directly contact the top surface of the channel layer 20. The spacer layer 22 may be comprised of a III-V compound semiconductor material. In an embodiment, the spacer layer 22 may be comprised of a binary III-V compound semiconductor material, such as aluminum nitride. In an embodiment, the III-V compound semiconductor material of the spacer layer 22 may be characterized by a higher electrical resistivity than the III-V compound semiconductor material of the channel layer 20. In an embodiment, the spacer layer 22 may have a thickness of about one (1) nanometer to about two (2) nanometers.

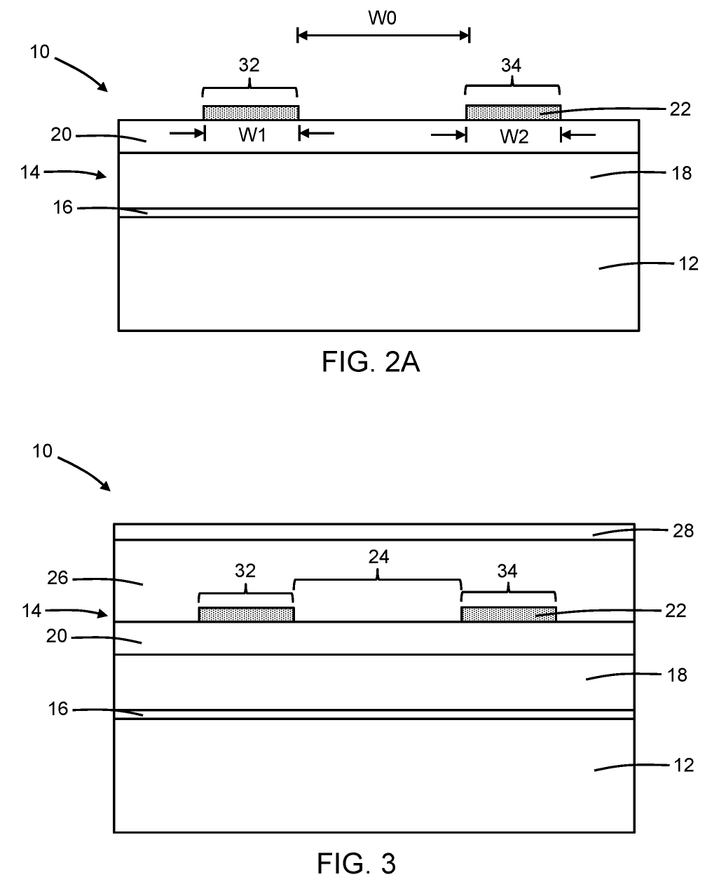

With reference to FIG. 2 in which like reference numerals refer to like features in FIG. 1 and at a subsequent fabrication stage, the spacer layer 22 may be patterned by lithography and etching processes into sections 32, 34 that are arranged and positioned on a top surface of the channel layer 20. The sections 32, 34 of the spacer layer 22 are surrounded by portions of the channel layer 20 that are exposed after the spacer layer 22 is patterned. The section 32 is spaced from the section 34 by a gap 24 that has a width dimension W0 such that the section 32 is disconnected and detached from the section 34 to provide a distinct lateral separation.

The section 32 may have a width W1 and a length L1 transverse to the width W1. The section 34 may have a width W2 and a length L2 transverse to the width W2. In an embodiment, the width W1 of the section 32 may be equal to the width W2 of the section 34. In an alternative embodiment, the width W1 of the section 32 and the width W2 of the section 34 may be unequal. In an embodiment, the length L1 of the section 32 may be equal to the length L2 of the section 34. In an alternative embodiment, the length L1 of the section 32 and the length L2 of the section 34 may be unequal. In an embodiment, the width W1 and length L1 of the section 32 may be equal to the width W2 and length L2 of the section 34. In an alternative embodiment, the width W1 and length L1 of the section 32 and the width W2 and length L2 of the section 34 may be unequal. In an embodiment, the sections 32, 34 may have equal thicknesses.

With reference to FIG. 3 in which like reference numerals refer to like features in FIGS. 2, 2A and at a subsequent fabrication stage, the layer stack 14 may further include a barrier layer 26 and a cap layer 28 that are formed after the spacer layer 22 is patterned to form the sections 32, 34. The sections 32, 34 of the spacer layer 22 are positioned as an interlayer between portions of the channel layer 20 and portions of the barrier layer 26. The barrier layer 26 also includes portions that are positioned in direct contact with the channel layer 20. The portions of the barrier layer 26 in direct contact with the channel layer 20 surround the sections 32, 34 of the spacer layer 22, which may also be in direct contact with the channel layer 20. For example, a portion of the barrier layer 26 fills the space laterally between the section 32 of the spacer layer 22 and the section 34 of the spacer layer 22.

The barrier layer 26 and cap layer 28 of the layer stack 14 may be serially deposited using an epitaxial growth process. The barrier layer 26 and cap layer 28 may have respective crystal structures that are single crystal or, alternatively, crystal structures that are substantially single crystal with a level of crystalline defectivity present. The barrier layer 26 may be comprised of a ternary III-V compound semiconductor, such as aluminum gallium nitride. The cap layer 28 may be comprised of a binary III-V compound semiconductor, such as gallium nitride. The layer stack 14, after the deposition of the barrier layer 26 and cap layer 28, may have a total thickness, for example, on the order of five (5) micrometers.

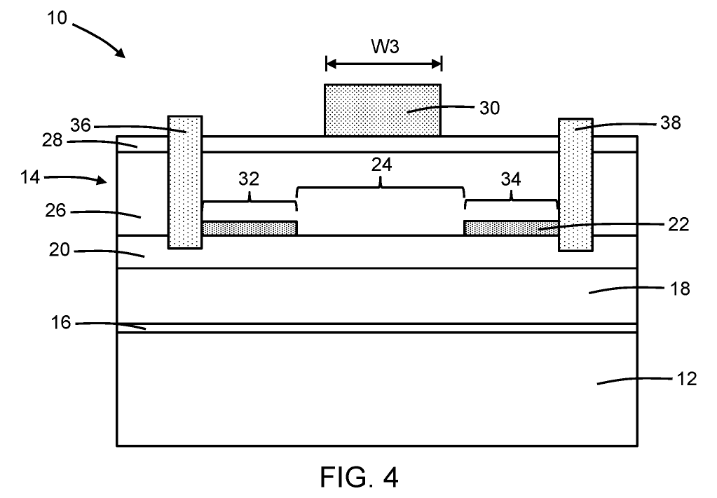

With reference to FIG. 4 in which like reference numerals refer to like features in FIG. 3 and at a subsequent fabrication stage, a gate 30, an ohmic contact 36, and an ohmic contact 38 may be formed that are positioned on different portions of the layer stack 14. The section 32 of the spacer layer 22 is positioned in a lateral direction between the gate 30 and the ohmic contact 36. The section 34 of the spacer layer 22 is positioned in a lateral direction between the gate 30 and the ohmic contact 38. The gate 30 is positioned in a lateral direction within the gap 24 (FIG. 2) between the section 32 of the spacer layer 22 and the section 34 of the spacer layer 22.

The gate 30 is positioned on a portion of the barrier layer 26 that overlies the gap 24 between the ohmic contact 36 and the ohmic contact 38, and the portion of the channel layer 20 is horizontally arranged between the section 32 of the spacer layer 22 and the section 34 of the spacer layer 22. In an embodiment, the gate 30 may directly contact the underlying portion of the channel layer 20 that is arranged within the gap 24 between the section 32 of the spacer layer 22 and the section 34 of the spacer layer 22. In an embodiment, the gate 30 may have a non-overlapping relationship with the section 32 of the spacer layer 22 and the section 34 of the spacer layer 22. The III-V compound semiconductor material of the barrier layer 26 overlies both of the sections 32, 34 of the spacer layer 22. The gate 30 may have a width dimension W3 that is less than the width dimension W0 of the gap 24 between the section 32 of the spacer layer 22 and the section 34 of the spacer layer 22.

In an embodiment, the ohmic contacts 36 and the ohmic contact 38 may be formed in respective recesses that penetrate fully through the barrier layer 26 and cap layer 28, and then to a given depth into the channel layer 20. In an embodiment, the ohmic contacts 36 may adjoin the section 32 of the spacer layer 22 and the ohmic contact 38 may adjoin the section 34 of the spacer layer 22.

The gate 30 may be comprised of a doped III-V compound semiconductor material, such as gallium nitride containing a concentration of a p-type dopant, having a crystal structure that is either single crystal or substantially single crystal. The gate 30 may be formed from a semiconductor layer that is deposited using an epitaxial growth process and patterned by lithography and etching processes. The ohmic contacts 36, 38 may contain a mixture of polycrystalline grains that are comprised of aluminum, titanium, and silicon and polycrystalline grains that are comprised of aluminum. In an embodiment, the ohmic contacts 36, 38 may be formed by depositing a layer stack including layers of aluminum, titanium, and silicon, performing a rapid thermal anneal to induce the formation of the polycrystalline grains, and patterning.

The gate 30, the ohmic contact 36, and the ohmic contact 38 may represent respective terminals of the high-electron-mobility transistor. In an embodiment, the ohmic contact 36 may represent a source terminal of the of the high-electron-mobility transistor embodied in the structure 10, and the ohmic contact 38 may represent a drain terminal of the high-electron-mobility transistor embodied in the structure 10.

An interconnect structure (not shown) may be formed that includes contacts, vias, and wiring that are coupled to the gate 30, the ohmic contact 36, and the ohmic contact 38 of the high-electron-mobility transistor embodied in the structure 10. The interconnect structure may also include field plates that assist with device performance during operation.

The high-electron-mobility transistor embodied in the structure 10 may exhibit improved electrical parameters because of the patterning of the spacer layer 22 into the sections 32, 34, which contrasts with conventional device structures in which the spacer layer is continuous and not patterned. The patterned spacer layer 22 provide an interlayer with sections 32, 34 that are situated between adjoining portions of the channel layer 20 and the barrier layer 26. The material of the spacer layer 22 may be characterized by a higher electrical resistivity than either the material of the channel layer 20 or the material of the barrier layer 26. The patterning of the spacer layer 22 into sections 32, 34 lowers the contribution of the resistance of the high-resistance spacer layer 22 to the total device resistance, which may improve electrical parameters such as on-resistance and transconductance.

The removal of the spacer layer 22 beneath the gate 30 may alter the depletion of the two-dimensional electron gas underneath the gate 30, which may function to increase the threshold voltage to a value that is greater than zero (0) volts. In contrast to conventional high-electron-mobility transistors, this permits the high-electron-mobility transistor embodied in the structure 10 to operate in a normally on-state with a positive threshold voltage.

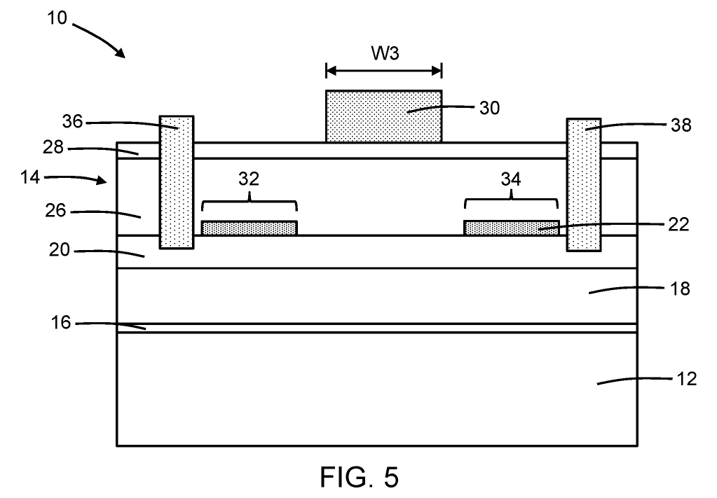

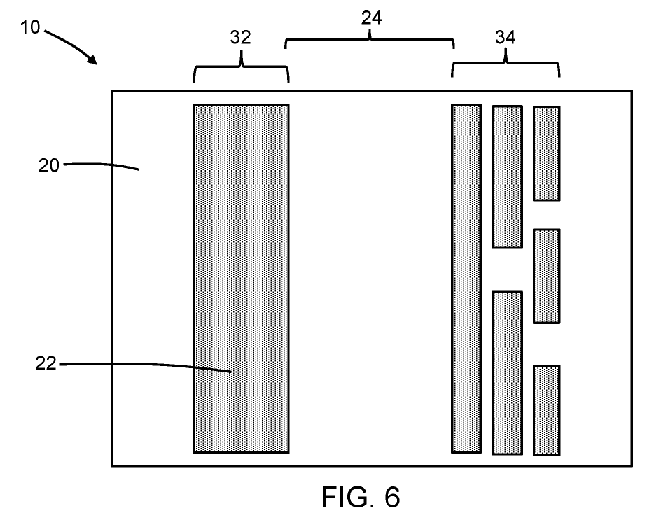

With reference to FIG. 5 and in accordance with alternative embodiments, the ohmic contacts 36 may be spaced outward from the section 32 of the spacer layer 22 and away from the gate 30 and therefore separated from the section 32 by a gap instead of being in direct contact. Similarly, the ohmic contact 38 may be spaced outward from the section 34 of the spacer layer 22 away from the gate 30 and therefore separated from the section 34 by a gap instead of being in direct contact.

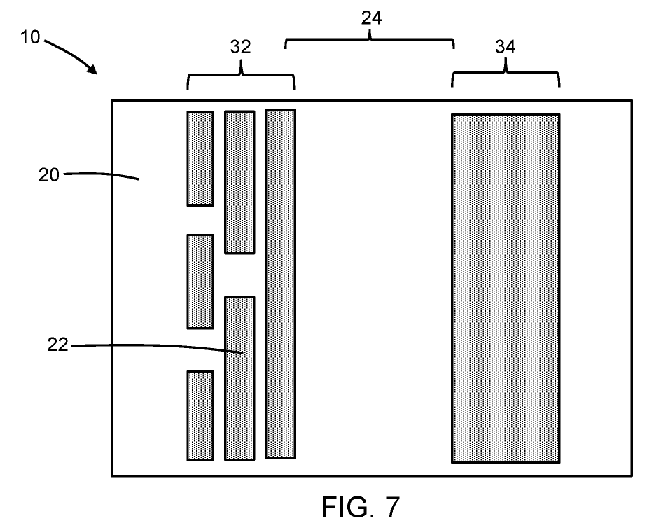

With reference to FIG. 6 and in accordance with alternative embodiments, the spacer layer 22 include multiple sections 34 that are formed when the spacer layer 22 is patterned. In an embodiment, the sections 34 may have non-uniform shapes and sizes from a perspective normal to the top surface of the sections 34. In an embodiment, the section 34 closest to the subsequently-formed gate 30 may be the largest in size. In an embodiment, the number of individual sections 34, which are disconnected and detached from each other, may be greater than or equal to two (2).

The process flow continues with the formation of the barrier layer 26 and the cap layer 28 to complete the layer stack 14, followed by the formation of the gate 30 and the ohmic contacts 36, 38. The multiple sections 34 are laterally arranged between the gate 30 and the ohmic contact 38.

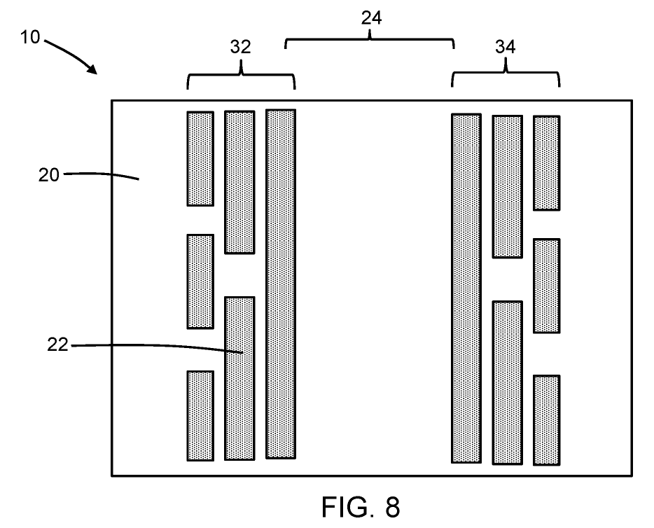

With reference to FIG. 7 and in accordance with alternative embodiments, the spacer layer 22 may include multiple sections 32 that are formed when the spacer layer 22 is patterned. In an embodiment, the sections 32 may have non-uniform shapes and sizes from a perspective normal to the top surface of the sections 32. In an embodiment, the section 32 closest to the subsequently-formed gate 30 may be the largest in size. In an embodiment, the number of individual sections 32, which are disconnected and detached from each other, may be greater than or equal to two (2).

The process flow continues with the formation of the barrier layer 26 and the cap layer 28 to complete the layer stack 14, followed by the formation of the gate 30 and the ohmic contacts 36, 38. The multiple sections 32 are laterally arranged between the gate 30 and the ohmic contact 36.

With reference to FIG. 8 and in accordance with alternative embodiments, the spacer layer 22 may include multiple sections 32 and multiple sections 34. In an embodiment, the sections 32 and the sections 34 may be identical in shapes, dimensions, number, and patterns. In an alternative embodiment, the sections 32 and the sections 34 may differ in shapes, dimensions, number, and/or patterns.

The process flow continues with the formation of the barrier layer 26 and the cap layer 28 to complete the layer stack 14, followed by the formation of the gate 30 and the ohmic contacts 36, 38. The multiple sections 32 are laterally arranged between the gate 30 and the ohmic contact 36, and the multiple sections 34 are laterally arranged between the gate 30 and the ohmic contact 38.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a layer stack including a first layer and a second layer on the first layer, the first layer comprising a first III-V compound semiconductor material, the second layer comprising a second III-V compound semiconductor material, and the second layer including a first section and a second section spaced from the first section by a gap; and
a high-electron-mobility transistor including a gate overlying the gap, the gate laterally positioned between the first section of the second layer and the second section of the second layer.

2. The structure of claim 1 further comprising:
a substrate,
wherein the layer stack is positioned on the substrate, and the first layer is positioned between the second layer and the substrate.

3. The structure of claim 1 wherein the layer stack includes a third layer positioned on the second layer, the third layer comprises a third III-V compound semiconductor material, and a portion of the third layer is positioned on the first layer inside the gap.

4. The structure of claim 3 wherein the gate is positioned on the portion of the third layer.

5. The structure of claim 4 wherein the gate has a non-overlapping relationship with the first section of the second layer and the second section of the second layer.

6. The structure of claim 4 wherein the gate is in direct contact with the portion of the first layer.

7. The structure of claim 3 wherein the portion of the first layer is horizontally positioned between the first section of the second layer and the second section of the second layer.

8. The structure of claim 1 wherein the high-electron-mobility transistor includes a first ohmic contact coupled to the layer stack, and the first section of the second layer is horizontally positioned between the gate and the first ohmic contact.

9. The structure of claim 8 wherein the high-electron-mobility transistor includes a second ohmic contact, the gate is laterally positioned between the first ohmic contact and the second ohmic contact, and the second section of the second layer is horizontally positioned between the gate and the second ohmic contact.

10. The structure of claim 9 wherein the second section of the second layer is horizontally positioned between the gate and the second ohmic contact.

11. The structure of claim 9 wherein the second layer includes a third section horizontally positioned between the gate and the second ohmic contact.

12. The structure of claim 9 wherein the second layer includes a third section horizontally positioned between the gate and the first ohmic contact, and the second layer includes a fourth section horizontally positioned between the gate and the second ohmic contact.

13. The structure of claim 8 wherein the second layer includes a third section horizontally positioned between the gate and the first ohmic contact.

14. The structure of claim 8 wherein the first ohmic contact is a source terminal of the high-electron-mobility transistor.

15. The structure of claim 8 wherein the first ohmic contact is a drain terminal of the high-electron-mobility transistor.

16. The structure of claim 1 wherein the second III-V compound semiconductor material is aluminum nitride.

17. The structure of claim 1 wherein the gate is spaced in a lateral direction from the first section of the second layer by a first distance, and the gate is spaced in the lateral direction from the second section of the second layer by a second distance.

18. The structure of claim 17 wherein the gap has a first width dimension, and the gate has a second width dimension that is less than the first width dimension.

19. The structure of claim 1 wherein the first section of the second layer is disconnected from the second section of the second layer.

20. A method comprising:
forming a layer stack including a first layer and a second layer on the first layer, wherein the first layer comprises a first III-V compound semiconductor material, the second layer comprises a second III-V compound semiconductor material, and the second layer includes a first section and a second section that is spaced from the first section by a gap; and
forming a high-electron-mobility transistor including a gate that overlies the gap, wherein the gate is laterally positioned between the first section of the second layer and the second section of the second layer.
